(19) United States
(12) Patent Application Publication
(10) Pub. No.: US 2024/0304545 A1
(43) Pub. Date: Sep. 12, 2024

(54) COUPLED INDUCTORS THROUGH SUBSTRATE-ASSEMBLY PROCESS AND/OR WAFER-LEVEL PROCESS

(71) Applicant: QUALCOMM Incorporated, San Diego, CA (US)

(72) Inventors: Kai LIU, Phoenix, AZ (US); Nosun PARK, San Diego, CA (US); Jonghae KIM, San Diego, CA (US)

(21) Appl. No.: 18/182,080

(22) Filed: Mar. 10, 2023

(51) Int. Cl. H01L 23/522; H01L 23/538

(52) U.S. Cl. CPC H01L 23/5227; H01L 23/5381; H01L 23/5384; H01L 23/5386; H01L 28/10

(57) ABSTRACT

Compact coupled inductor designs are disclosed. In an aspect, a coupled inductor comprises a pair of inductors, each inductor comprising an alternating series of metallization structures and wire bonds forming a spiral topology around a common central axis, wherein the pair of inductors are interleaved with each other along the common central axis, such that at least some of the metallization structures of one of the pair of inductors are electrically coupled with at least some of the metallization structures of the other of the pair of inductors, and at least some of the wire bonds of one of the pair of inductors are electrically coupled with at least some of the wire bonds of the other of the pair of inductors. The shapes of the wire bonds can be selected to produce a desired coupling coefficient.

### BACKGROUND OF THE DISCLOSURE

### 1. Field of the Disclosure

This disclosure relates generally to wafer level process coupled inductors, and more specifically, but not exclusively, to coupled inductors implemented using a substrate-assembly process and/or a wafer-level process.

### 2. Description of the Related Art

A highly-integrated electronics system, such as a system-on-chip (SOC) or multi-chip-module (MCM), require a power distribution network (PDN) that can provide stable, reliable power to all components within the system. The simplest PDN architecture is a single stage PDN, in which the output of an external voltage regulator (EVR) is routed to each chip, SOC, and/or MCM in the system. The EVR outputs a common supply voltage that is used by all of the components of the system, e.g., 1.0 volts. A better PDN architecture is a dual stage PDN, in which an EVR produces a higher, intermediate voltage, e.g., 1.8 volts, which is routed to each component in the system, and each component includes an integrated voltage regulator (IVR) to convert that intermediate voltage to the supply voltage needed by the component, e.g., 1.0 volts. Compared to a single stage PDN, a dual stage PDN has higher efficiencies at higher power consumptions, but requires that each component include its own IVR.

Coupled inductors are needed for IVR in certain applications, but conventional coupled inductor designs have disadvantages. For example, component inductors are large and therefore increase the size of the component to which they are attached, and must be attached to the individual component in an additional process step; thin film magnetic inductors (TFMIs) are small but have high processing costs and cannot be constructed to have the high inductances needed for IVR; other wafer-level inductor architectures cannot provide the high inductances needed for IVR or else require exotic materials that greatly increase the wafer processing costs (and sometimes significantly reduce wafer process yields, as well). Thus, there is a need for a better approach having none of the disadvantages described above.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a coupled inductor includes a pair of inductors, each inductor comprising an alternating series of metallization structures and wire bonds forming a spiral topology around a common central axis, wherein the pair of inductors are interleaved with each other along the common central axis such that at least some of the metallization structures of one of the pair of inductors are electrically coupled with at least some of the metallization structures of the other of the pair of inductors, and at least some of the wire bonds of one of the pair of inductors are electrically coupled with at least some of the wire bonds of the other of the pair of inductors.

In an aspect, a coupled inductor includes a pair of inductors, each inductor comprising an alternating series of lower-layer metallization structures and upper-layer metallization structures separated by an insulating layer and electrically connected to each other by vias through the insulating layer, and forming a spiral topology around a common central axis, wherein the pair of inductors are interleaved with each other along the common central axis, such that at least some of the lower-layer metallization structures of one of the pair of inductors are electrically coupled with at least some of the lower-layer metallization structures of the other of the pair of inductors, and at least some of the upper-layer metallization structures of one of the pair of inductors are electrically coupled with at least some of the upper-layer metallization structures of the other of the pair of inductors.

In an aspect, a method for fabricating a coupled inductor includes providing a substrate; forming, on the substrate, a plurality of metallization structures, each metallization structure comprising a plurality of metal layers electrically connected in parallel with each other; and connecting the plurality of metallization structures using wire bonds to create a pair of inductors, each inductor comprising an alternating series of metallization structures and wire bonds forming a spiral topology around a common central axis, wherein the pair of inductors are interleaved with each other along the common central axis, such that at least some of the metallization structures of one of the pair of inductors are electrically coupled with at least some of the metallization structures of the other of the pair of inductors, and at least some of the wire bonds of one of the pair of inductors are electrically coupled with at least some of the wire bonds of the other of the pair of inductors.

In an aspect, a method for fabricating a coupled inductor includes providing a substrate; forming, on the substrate, a plurality of first-level metallization structures, each first-level metallization structure comprising a plurality of metal layers electrically connected in parallel with each other; forming an insulating layer above the plurality of first-level metallization structures; forming a plurality of vias that are electrically coupled to the plurality of first-level metallization structures through the insulating layer; and forming, on the insulating layer, a plurality of second-level metallization structures to create a pair of inductors, each inductor comprising an alternating series of first-level metallization structures and second-level metallization structures separated by the insulating layer and electrically connected to each other by the vias through the insulating layer, and forming a spiral topology around a common central axis, wherein the pair of inductors are interleaved with each other along the common central axis, such that at least some of the first-level metallization structures of one of the pair of inductors are electrically coupled with at least some of the first-level metallization structures of the other of the pair of inductors, and at least some of the second-level metallization structures of one of the pair of inductors are electrically coupled with at least some of the second-level metallization structures of the other of the pair of inductors.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1 illustrates an example multi-component system having a single stage power distribution network (PDN).

FIG. 2 illustrates an example multi-component system having a dual stage PDN.

FIG. 3 is a graph that compares efficiency versus power for a single stage PDN versus a dual stage PDN.

FIG. 4 is a schematic 400 of a portion of an IVR design that uses mutually coupled inductors L1 and L2.

FIG. 5 is a top view of a coupled inductor 500 according to aspects of the disclosure.

FIG. 6A and FIG. 6B are side and isometric views, respectively, of a coupled inductor according to aspects of the disclosure.

FIG. 6C and FIG. 6D are side and isometric views, respectively, of a coupled inductor according to aspects of the disclosure.

FIG. 7 is a top view of a coupled inductor according to aspects of the disclosure.

FIG. 8 is a flowchart of an example process 800 associated with coupled inductors with laminate substrate and bonding wires, according to aspects of the disclosure.

FIG. 9 is a flowchart of an example process 900 associated with coupled inductors with laminate substrate and magnetic insulating layer, according to aspects of the disclosure.

FIG. 10 illustrates various electronic devices that may be integrated with any of the aforementioned coupled inductors in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Compact coupled inductor designs are disclosed. In an aspect, a coupled inductor comprises a pair of inductors, each inductor comprising an alternating series of metallization structures and wire bonds forming a spiral topology around a common central axis, wherein the pair of inductors are interleaved with each other along the common central axis such that at least some of the metallization structures of one of the pair of inductors are electrically coupled with at least some of the metallization structures of the other of the pair of inductors, and at least some of the wire bonds of one of the pair of inductors are electrically coupled with at least some of the wire bonds of the other of the pair of inductors. The shapes of the wire bonds can be selected to produce a desired coupling coefficient.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

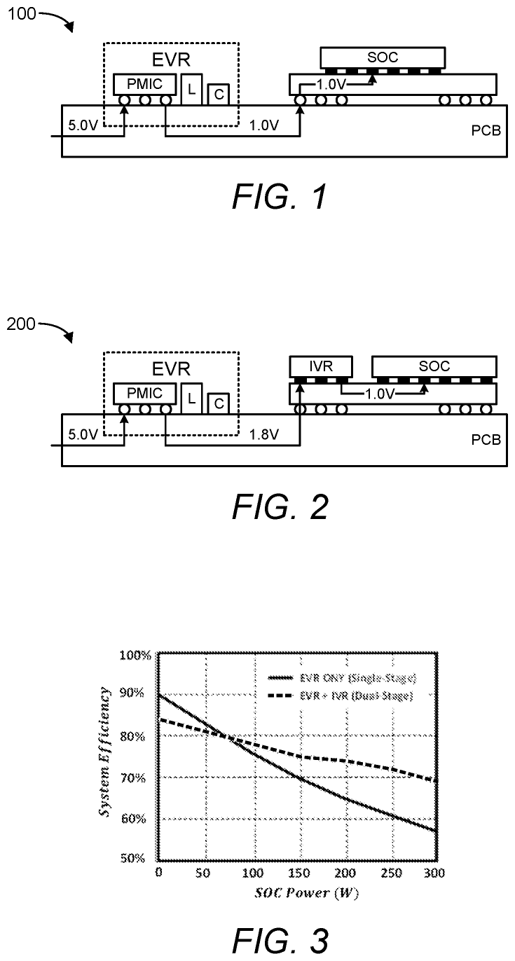

FIG. 1 illustrates an example multi-component system 100 having a single stage power distribution network (PDN). In system 100, a system supply voltage (e.g., 5.0V) is supplied to an external voltage regulator (EVR) circuit that outputs a system-on-chip (SOC) supply voltage (e.g., 1.0V). One advantage of a single stage PDN is its simplicity—the EVR provides the SOC operating voltage directly, but a disadvantage is that the distance between the EVR output and the SOC inputs may be relatively long and may suffer a voltage drop or resistive power loss.

FIG. 2 illustrates an example multi-component system 200 having a dual stage PDN. In system 200, a system supply voltage (e.g., 5.0V) is provided to an EVR that outputs an intermediate voltage (e.g., 1.8V), which is routed to the SOC. The SOC includes an integrated voltage regulator (IVR) that converts the intermediate voltage (e.g., 1.8V) to the supply voltage required by the SOC (e.g., 1.0V). In part because the EVR provides a higher voltage to the SOC, the dual stage PDN design has better power efficiency when compared to the single stage PDN design.

FIG. 3 is a graph that compares efficiency versus power for a single stage PDN versus a dual stage PDN. As can be seen in the graph in FIG. 3, as the SOC power increases, the system efficiency of a single stage PDN decreases at a faster rate than the system efficiency of a dual stage PDN, meaning that the dual stage PDN is more efficient than the single stage PDN at higher SOC power values. Thus, there are advantages to using a dual stage PDN. However, a dual stage PDN requires that each consumer (e.g., the SOC) have an IVR, and IVR designs can incorporate mutually coupled inductors.

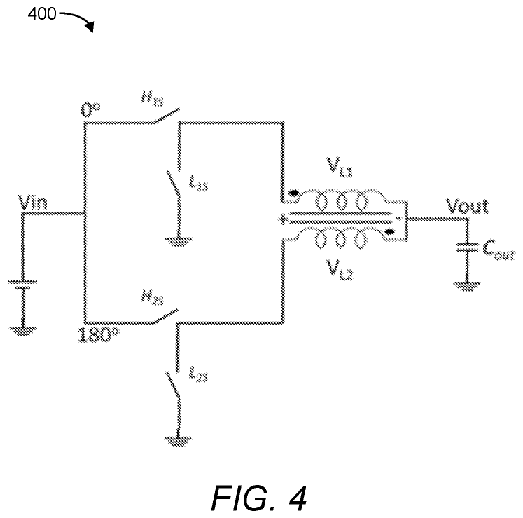

FIG. 4 is a schematic 400 of a portion of an IVR design that uses mutually coupled inductors L1 and L2. In the example shown in FIG. 4, an input voltage Vin is provided to both L1 and L2 via a switching network that couples one end of each inductor to Vin (via switches H _{1S} and H_{2S}) or to ground (via switches L_{1S} and L_{2S}). The other end of each inductor are tied together to produce Vout. The timing of the opening and closing of switches H_{1S}, H_{2S}, L_{1S}, and L_{2S} produces the desired output voltage at Vout across a smoothing capacitor C_{OUT}, e.g., the 1.0 volts needed by the SOC in FIG. 3B. The instantaneous voltage across L1 is V_{L1} and the instantaneous voltage across L2 is V_{L2}. In the specific design shown in FIG. 4, one inductor is one hundred and eighty degrees out of phase from the other inductor, but this aspect, and others, are illustrative and not limiting.

Coupled inductors are needed for IVR in certain applications, but conventional coupled inductor designs have disadvantages. For example, component inductors are large and therefore increase the size of the component to which they are attached, and must be attached to the individual component in an additional process step; thin film magnetic inductors (TFMIs) are small but have high processing costs and cannot be constructed to have the high inductances needed for IVR; other wafer-level inductor architectures cannot provide the high inductances needed for IVR or else require exotic materials that greatly increase the wafer processing costs (and sometimes significantly reduce wafer process yields, as well).

Accordingly, designs for coupled inductors having the high inductances needed for IVR and constructed using a cost-effective process are presented herein. More specifically, coupled inductors that are constructed using a conventional substrate process, conventional wire-bonding techniques, and a magnetic mold compound (MMC) are disclosed, as well as techniques for making the same.

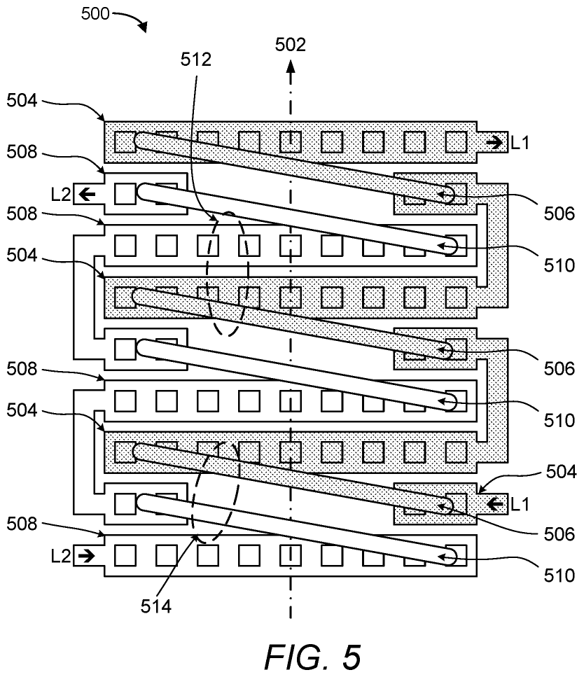

FIG. 5 is a top view of a coupled inductor 500 according to aspects of the disclosure. The coupled inductor 500 comprises a pair of inductors, each inductor comprising an alternating series of metallization structures and wire bonds forming a spiral topology around a common central axis 502. In the example shown in FIG. 5, a first inductor (L1) comprises an alternating series of metallization structures 504 and wire bonds 506, while a second inductor (L2) comprises an alternating series of metallization structures 508 and wire bonds 510. The pair of inductors are interleaved with each other along the common central axis 502, such that at least some of the metallization structures 504 of L1 are electrically coupled (shown as 512) with at least some of the metallization structures 508 of L2, and at least some of the wire bonds 506 of L1 are electrically coupled (shown as 514) with at least some of the wire bonds 510 of L2.

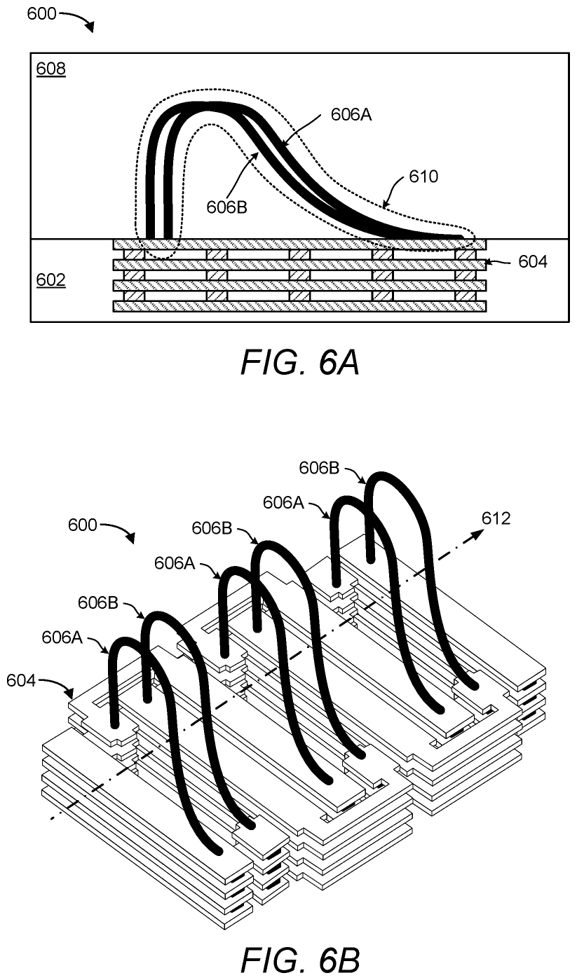

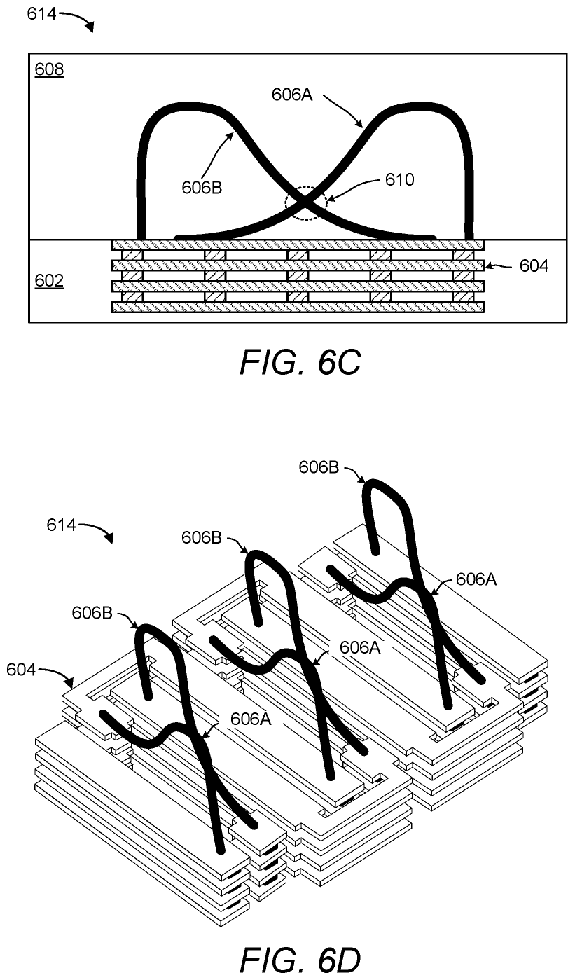

FIG. 6A and FIG. 6B are side and isometric views, respectively, of a coupled inductor 600 according to aspects of the disclosure. As shown in FIG. 6A, the coupled inductor 600 comprises a substrate 602 in which is embedded a multi-level metallization structure 604. In some aspects, the metallization structure 604 comprises multiple metal layers in a vertical stack, electrically connected together with vias. The metallization structure 604 comprises distinct components electrically connected to each other by wire bonds 606A and 606B, which may be collectively referred to herein as “wire bonds 606.” In the example shown in FIGS. 6A and 6B, the wire bonds of one inductor are labeled as 606A and the wire bonds of the other inductor are labeled as 606B. In the example shown in FIG. 6A, the wire bonds 606A and 606B have essentially the same side profile, which results in a coupling area 610 along a significant portion of the lengths of the wire bonds 606. As seen in FIG. 6B, the conductors form an interleaved spiral around a common central axis 612. In some aspects, the wire bonds 606 are surrounded by (or embedded within) a molding compound 608, which stabilizes the wire bonds 606. In some aspects, the molding compound 608 is a magnetic molding compound, which increases the individual and mutual inductances and thus improves performance. In one implementation, the measured coupling coefficient was 40%.

FIG. 6C and FIG. 6D are side and isometric views, respectively, of a coupled inductor 614 according to aspects of the disclosure. Like the coupled inductor 600 shown in FIG.

6A, the coupled inductor 614 shown in FIG. 6C comprises a substrate 602 in which is embedded a multi-level metallization structure 604 that comprises distinct components electrically connected to each other by wire bonds 606. In the example shown in FIG. 6C and FIG. 6D, however, the wire bonds 606A and 606B have different side profiles, which results in a coupling area 610 along only a small part of the lengths of the wire bonds 606. In some aspects, the wire bonds 606 are surrounded by (or embedded within) a molding compound 608, which stabilizes the wire bonds 606. In some aspects, the molding compound 608 is a magnetic molding compound, which can increase the individual and mutual inductances by 20-30% and thus improves performance. In one implementation, the measured coupling coefficient was 18%.

Thus, in some aspects, the mutual inductance of a coupled inductor can be controlled to some extent by controlling the relative profiles of the wire bonds of each separate inductor. The mutual inductance of coupled inductor 600 will be larger than the mutual inductance of coupled inductor 614, e.g., median (˜40%) for coupled inductor 600 and weak (˜18%) for coupled inductor 614.

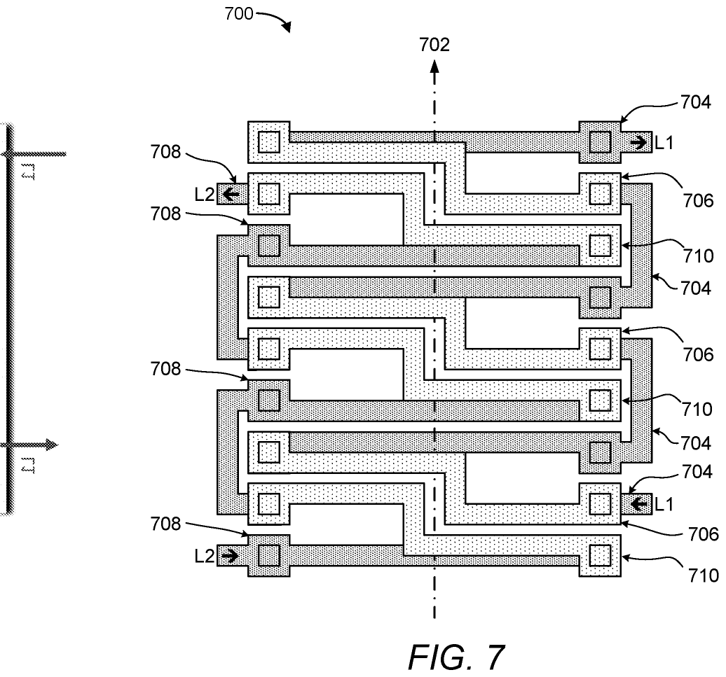

FIG. 7 is a top view of a coupled inductor 700 according to aspects of the disclosure. The coupled inductor 700 comprises a pair of inductors, each inductor comprising an alternating series of metallization structures forming a spiral topology around a common central axis 702. In the example shown in FIG. 7, a first inductor (L1) comprises an alternating series of lower level metallization structures 704 and upper level metallization structures 706, while a second inductor (L2) comprises an alternating series of lower level metallization structures 708 and upper level metallization structures 710. The pair of inductors are interleaved with each other along the common central axis 702, such that at least some of the lower level metallization structures 704 of L1 are electrically coupled with at least some of the lower level metallization structures 708 of L2, and at least some of the upper level metallization structures 706 of L1 are electrically coupled with at least some of the upper level metallization structures 710 of L2. This structure may be referred to herein as wafer-level coupled inductors. In some aspects, the upper level metallization structures are electrically connected to the lower level metallization structures using vias. In some aspects, the upper level metallization structures and the lower level metallization structures are separated by a magnetic material, which is traversed by the vias. Thus, the vias are surrounded by the magnetic material. In one implementation, the measured coupling coefficient was 21%.

The coupled inductors disclosed herein have the technical advantage that they can be constructed in a cost-effective manner, e.g., using conventional substrate, wire bonding, and molding processes. Additionally, the shapes of the wire bonds can be used to produce a desired coupling coefficient within a particular range.

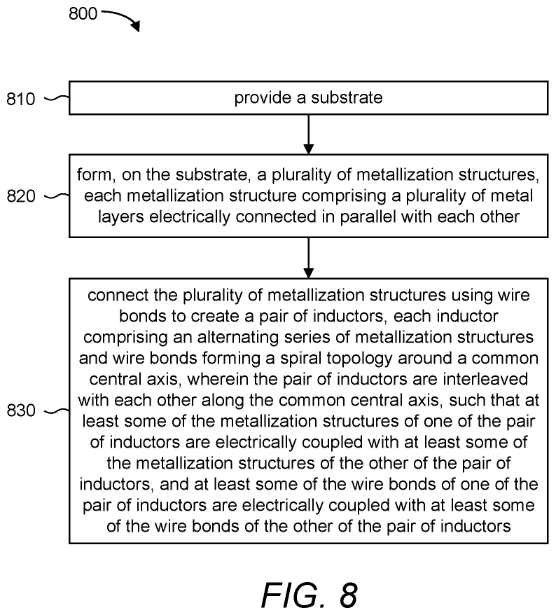

FIG. 8 is a flowchart of an example process 800 associated with coupled inductors with laminate substrate and bonding wires, according to aspects of the disclosure. As shown in FIG. 8, process 800 may include, at block 810, providing a substrate. In some aspects, the substrate comprises a laminate substrate. In some aspects, the substrate will be used only for coupled inductors. In some aspects, the substrate will include the coupled inductors and additional circuitry, such as an IVR. In some aspects, the substrate will be part of a larger SOC that includes an IVR.

As further shown in FIG. 8, process 800 may include, at block 820, forming, on the substrate, a plurality of metallization structures, each metallization structure comprising a plurality of metal layers electrically connected in parallel with each other. In some aspects, forming the plurality of metallization structures comprises forming the plurality of metal layers in a vertical stack, separated from each other by a respective insulating layer, and electrically connected to each other by one or more vias through the respective insulating layer. In some aspects, forming the plurality of metallization structures comprises forming the plurality of metallization structures using a wafer-level process (WLP). In some aspects, forming the plurality of metallization structures comprises forming at least one redistribution layer (RDL).

As further shown in FIG. 8, process 800 may include, at block 830, connecting the plurality of metallization structures using wire bonds to create a pair of inductors, each inductor comprising an alternating series of metallization structures and wire bonds forming a spiral topology around a common central axis, wherein the pair of inductors are interleaved with each other along the common central axis such that at least some of the metallization structures of one of the pair of inductors are electrically coupled with at least some of the metallization structures of the other of the pair of inductors, and at least some of the wire bonds of one of the pair of inductors are electrically coupled with at least some of the wire bonds of the other of the pair of inductors.

In some aspects, process 800 includes encasing the wire bonds within an insulating material. In some aspects, encasing the wire bonds within an insulating material comprise encasing the wire bonds within a magnetic molding compound.

Process 800 may include additional implementations, such as any single implementation or any combination of implementations described below and/or in connection with one or more other processes described elsewhere herein. Although FIG. 8 shows example blocks of process 800, in some implementations, process 800 may include additional blocks, fewer blocks, different blocks, or differently arranged blocks than those depicted in FIG.

8. Additionally, or alternatively, two or more of the blocks of process 800 may be performed in parallel.

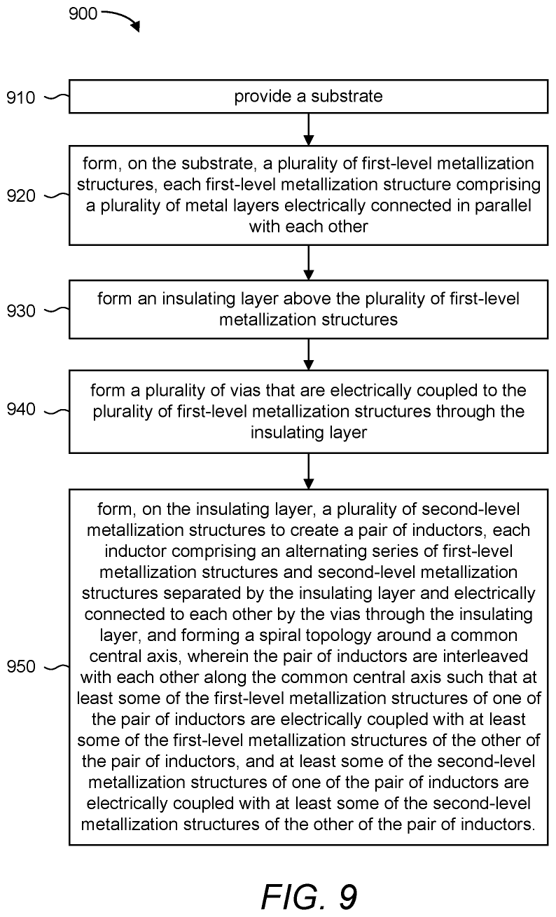

FIG. 9 is a flowchart of an example process 900 associated with coupled inductors with laminate substrate and magnetic insulating layer, according to aspects of the disclosure. As shown in FIG. 9, process 900 may include, at block 910, providing a substrate. In some aspects, the substrate comprises a laminate substrate. In some aspects, the substrate will be used only for coupled inductors. In some aspects, the substrate will include the coupled inductors and additional circuitry, such as an IVR. In some aspects, the substrate will be part of a larger SOC that includes an IVR.

As further shown in FIG. 9, process 900 may include, at block 920, forming, on the substrate, a plurality of first-level metallization structures, each first-level metallization structure comprising a plurality of metal layers electrically connected in parallel with each other. In some aspects, forming the plurality of first-level metallization structures comprises forming the plurality of first-level metal layers in a vertical stack, separated from each other by a respective insulating layer, and electrically connected to each other by one or more vias through the respective insulating layer. In some aspects, forming the plurality of first-level metallization structures comprises forming the plurality of first-level metallization structures using a wafer-level process (WLP). In some aspects, forming the plurality of first-level metallization structures comprises forming at least one redistribution layer (RDL).

As further shown in FIG. 9, process 900 may include, at block 930, forming an insulating layer above the plurality of first-level metallization structures. In some aspects, forming the insulating layer comprises forming a magnetic mold compound layer.

As further shown in FIG. 9, process 900 may include, at block 940, forming a plurality of vias that are electrically coupled to the plurality of first-level metallization structures through the insulating layer. In some aspects, the plurality of vias may be formed using standard photolithography techniques, such as etching, sputtering, etc.

As further shown in FIG. 9, process 900 may include, at block 950, forming, on the insulating layer, a plurality of second-level metallization structures to create a pair of inductors, each inductor comprising an alternating series of first-level metallization structures and second-level metallization structures separated by the insulating layer and electrically connected to each other by the vias through the insulating layer, and forming a spiral topology around a common central axis, wherein the pair of inductors are interleaved with each other along the common central axis, such that at least some of the first-level metallization structures of one of the pair of inductors are electrically coupled with at least some of the first-level metallization structures of the other of the pair of inductors, and at least some of the second-level metallization structures of one of the pair of inductors are electrically coupled with at least some of the second-level metallization structures of the other of the pair of inductors. In some aspects, forming the plurality of second-level metallization structures comprises forming the plurality of second-level metal layers in a vertical stack, separated from each other by a respective insulating layer, and electrically connected to each other by one or more vias through the respective insulating layer. In some aspects, forming the plurality of second-level metallization structures comprises forming the plurality of second-level metallization structures using a wafer-level process (WLP). In some aspects, forming the plurality of second-level metallization structures comprises forming at least one redistribution layer (RDL).

Process 900 may include additional implementations, such as any single implementation or any combination of implementations described below and/or in connection with one or more other processes described elsewhere herein. Although FIG. 9 shows example blocks of process 900, in some implementations, process 900 may include additional blocks, fewer blocks, different blocks, or differently arranged blocks than those depicted in FIG. 9. Additionally, or alternatively, two or more of the blocks of process 900 may be performed in parallel.

In some aspects, the coupled inductors described herein may be incorporated into an IVR. In some aspects, the IVR may be mounted to or incorporated into a SOC device. In some aspects, the SOC device may be incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

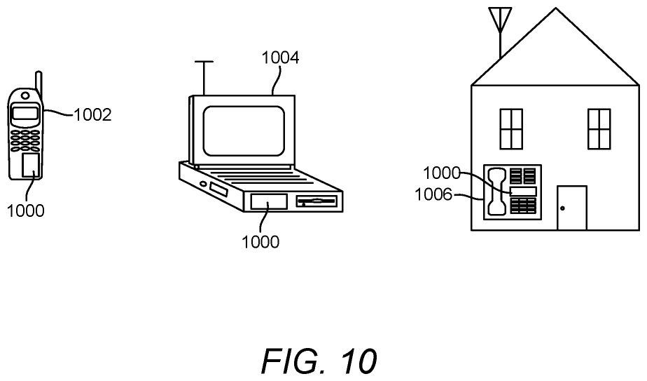

FIG. 10 illustrates various electronic devices that may be integrated with any of the aforementioned coupled inductors in accordance with various examples of the disclosure.

For example, a mobile phone device 1002, a laptop computer device 1004, and a fixed location terminal device 1006 may each be considered generally user equipment (UE) and may include a coupled inductor 1000 as described herein, for example. The device may be, for example, any of the integrated circuits, dies, integrated devices, integrated device packages, integrated circuit devices, device packages, integrated circuit (IC) packages, package-on-package devices described herein. The mobile phone device 1002, laptop computer device 1004, and fixed location terminal device 1006 illustrated in FIG. 10 are merely exemplary. Other electronic devices may also feature a coupled inductor 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A coupled inductor, comprising: a pair of inductors, each inductor comprising an alternating series of metallization structures and wire bonds forming a spiral topology around a common central axis, wherein the pair of inductors are interleaved with each other along the common central axis, such that at least some of the metallization structures of one of the pair of inductors are electrically coupled with at least some of the metallization structures of the other of the pair of inductors, and at least some of the wire bonds of one of the pair of inductors are electrically coupled with at least some of the wire bonds of the other of the pair of inductors.

Clause 2. The coupled inductor of clause 1, wherein a mutual inductance between the pair of inductors is controlled at least in part by shapes and orientations of the respective wire bonds of each inductor of the pair of inductors.

Clause 3. The coupled inductor of clause 2, wherein the shapes and orientations of the wire bonds of one of the pair of inductors are substantially identical to the shapes and orientations of the wire bonds of the other of the pair of inductors to minimize an average distance between wire bond portions of the respective inductors.

Clause 4. The coupled inductor of clause 2, wherein the shapes and orientations of the wire bonds of one of the pair of inductors are substantially different from the shapes and orientations of the wire bonds of the other of the pair of inductors to maximize an average distance between wire bond portions of the respective inductors.

Clause 5. The coupled inductor of any of clauses 1 to 4, wherein the metallization structures of each of the pair of inductors comprises a plurality of metal layers electrically connected in parallel with each other.

Clause 6. The coupled inductor of clause 5, wherein the plurality of metal layers electrically connected in parallel with each other comprises a plurality of metal layers in a vertical stack, separated from each other by a respective insulating layer, and electrically connected to each other by one or more vias through the respective insulating layer.

Clause 7. The coupled inductor of any of clauses 5 to 6, wherein the metallization structures comprise metallization structures created using a wafer-level process (WLP).

Clause 8. The coupled inductor of clause 7, wherein the metallization structures comprise at least one redistribution layer (RDL).

Clause 9. The coupled inductor of any of clauses 1 to 8, wherein the wire bonds are surrounded by an insulating material.

Clause 10. The coupled inductor of clause 9, wherein the insulating material comprises a magnetic molding compound.

Clause 11. The coupled inductor of any of clauses 1 to 10, wherein the coupled inductor is incorporated into an integrated voltage regulator circuit.

Clause 12. The coupled inductor of clause 11, wherein the integrated voltage regulator circuit is incorporated into system-on-chip (SOC) device.

Clause 13. The coupled inductor of clause 12, wherein the SOC device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 14. A coupled inductor, comprising: a pair of inductors, each inductor comprising an alternating series of lower-layer metallization structures and upper-layer metallization structures separated by an insulating layer and electrically connected to each other by vias through the insulating layer, and forming a spiral topology around a common central axis, wherein the pair of inductors are interleaved with each other along the common central axis such that at least some of the lower-layer metallization structures of one of the pair of inductors are electrically coupled with at least some of the lower-layer metallization structures of the other of the pair of inductors, and at least some of the upper-layer metallization structures of one of the pair of inductors are electrically coupled with at least some of the upper-layer metallization structures of the other of the pair of inductors.

Clause 15. The coupled inductor of clause 14, wherein at least some of the lower-layer metallization structures or upper-layer metallization structures of each of the pair of inductors comprises a plurality of metal layers electrically connected in parallel with each other.

Clause 16. The coupled inductor of clause 15, wherein the plurality of metal layers electrically connected in parallel with each other comprises a plurality of metal layers in a vertical stack, separated from each other by a respective insulating layer, and electrically connected to each other by one or more vias through the respective insulating layer.

Clause 17. The coupled inductor of any of clauses 15 to 16, wherein the metallization structures comprise metallization structures created using a wafer-level process (WLP).

Clause 18. The coupled inductor of clause 17, wherein the metallization structures comprise at least one redistribution layer (RDL).

Clause 19. The coupled inductor of any of clauses 14 to 18, wherein the insulating layer comprises a magnetic molding compound.

Clause 20. The coupled inductor of any of clauses 14 to 19, wherein the coupled inductor is incorporated into an integrated voltage regulator circuit.

Clause 21. The coupled inductor of clause 20, wherein the integrated voltage regulator circuit is incorporated into system-on-chip (SOC) device.

Clause 22. The coupled inductor of clause 21, wherein the SOC device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 23. A method for fabricating a coupled inductor, the method comprising:

providing a substrate; forming, on the substrate, a plurality of metallization structures, each metallization structure comprising a plurality of metal layers electrically connected in parallel with each other; and connecting the plurality of metallization structures using wire bonds to create a pair of inductors, each inductor comprising an alternating series of metallization structures and wire bonds forming a spiral topology around a common central axis, wherein the pair of inductors are interleaved with each other along the common central axis such that at least some of the metallization structures of one of the pair of inductors are electrically coupled with at least some of the metallization structures of the other of the pair of inductors and at least some of the wire bonds of one of the pair of inductors are electrically coupled with at least some of the wire bonds of the other of the pair of inductors.

Clause 24. The method of clause 23, wherein forming the plurality of metallization structures comprises forming the plurality of metal layers in a vertical stack, separated from each other by a respective insulating layer, and electrically connected to each other by one or more vias through the respective insulating layer.

Clause 25. The method of any of clauses 23 to 24, wherein forming the plurality of metallization structures comprises forming the plurality of metallization structures using a wafer-level process (WLP).

Clause 26. The method of clause 25, wherein forming the plurality of metallization structures comprises forming at least one redistribution layer (RDL).

Clause 27. The method of any of clauses 23 to 26, further comprising encasing the wire bonds within an insulating material.

Clause 28. The method of clause 27, wherein encasing the wire bonds within an insulating material comprise encasing the wire bonds within a magnetic molding compound.

Clause 29. A method for fabricating a coupled inductor, the method comprising:

providing a substrate; forming, on the substrate, a plurality of first-level metallization structures, each first-level metallization structure comprising a plurality of metal layers electrically connected in parallel with each other; forming an insulating layer above the plurality of first-level metallization structures; forming a plurality of vias that are electrically coupled to the plurality of first-level metallization structures through the insulating layer; and forming, on the insulating layer, a plurality of second-level metallization structures to create a pair of inductors, each inductor comprising an alternating series of first-level metallization structures and second-level metallization structures separated by the insulating layer and electrically connected to each other by the vias through the insulating layer, and forming a spiral topology around a common central axis, wherein the pair of inductors are interleaved with each other along the common central axis, such that at least some of the first-level metallization structures of one of the pair of inductors are electrically coupled with at least some of the first-level metallization structures of the other of the pair of inductors, and at least some of the second-level metallization structures of one of the pair of inductors are electrically coupled with at least some of the second-level metallization structures of the other of the pair of inductors.

Clause 30. The method of clause 29, wherein forming the insulating layer comprises forming a magnetic mold compound layer.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A coupled inductor, comprising:
a pair of inductors, each inductor comprising an alternating series of metallization structures and wire bonds forming a spiral topology around a common central axis,
wherein the pair of inductors are interleaved with each other along the common central axis, such that at least some of the metallization structures of one of the pair of inductors are electrically coupled with at least some of the metallization structures of the other of the pair of inductors, and at least some of the wire bonds of one of the pair of inductors are electrically coupled with at least some of the wire bonds of the other of the pair of inductors.

2. The coupled inductor of claim 1, wherein a mutual inductance between the pair of inductors is controlled at least in part by shapes and orientations of the respective wire bonds of each inductor of the pair of inductors.

3. The coupled inductor of claim 2, wherein the shapes and orientations of the wire bonds of one of the pair of inductors are substantially identical to the shapes and orientations of the wire bonds of the other of the pair of inductors to minimize an average distance between wire bond portions of the respective inductors.

4. The coupled inductor of claim 2, wherein the shapes and orientations of the wire bonds of one of the pair of inductors are substantially different from the shapes and orientations of the wire bonds of the other of the pair of inductors to maximize an average distance between wire bond portions of the respective inductors.

5. The coupled inductor of claim 1, wherein the metallization structures of each of the pair of inductors comprises a plurality of metal layers electrically connected in parallel with each other.

6. The coupled inductor of claim 5, wherein the plurality of metal layers electrically connected in parallel with each other comprises a plurality of metal layers in a vertical stack, separated from each other by a respective insulating layer, and electrically connected to each other by one or more vias through the respective insulating layer.

7. The coupled inductor of claim 5, wherein the metallization structures comprise metallization structures created using a wafer-level process (WLP).

8. The coupled inductor of claim 7, wherein the metallization structures comprise at least one redistribution layer (RDL).

9. The coupled inductor of claim 1, wherein the wire bonds are surrounded by an insulating material.

10. The coupled inductor of claim 9, wherein the insulating material comprises a magnetic molding compound.

11. The coupled inductor of claim 1, wherein the coupled inductor is incorporated into an integrated voltage regulator circuit.

12. The coupled inductor of claim 11, wherein the integrated voltage regulator circuit is incorporated into system-on-chip (SOC) device.

13. The coupled inductor of claim 12, wherein the SOC device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

14. A coupled inductor, comprising:
a pair of inductors, each inductor comprising an alternating series of lower-layer metallization structures and upper-layer metallization structures separated by an insulating layer and electrically connected to each other by vias through the insulating layer, and forming a spiral topology around a common central axis,
wherein the pair of inductors are interleaved with each other along the common central axis such that at least some of the lower-layer metallization structures of one of the pair of inductors are electrically coupled with at least some of the lower-layer metallization structures of the other of the pair of inductors, and at least some of the upper-layer metallization structures of one of the pair of inductors are electrically coupled with at least some of the upper-layer metallization structures of the other of the pair of inductors.

15. The coupled inductor of claim 14, wherein at least some of the lower-layer metallization structures or upper-layer metallization structures of each of the pair of inductors comprises a plurality of metal layers electrically connected in parallel with each other.

16. The coupled inductor of claim 15, wherein the plurality of metal layers electrically connected in parallel with each other comprises a plurality of metal layers in a vertical stack, separated from each other by a respective insulating layer, and electrically connected to each other by one or more vias through the respective insulating layer.

17. The coupled inductor of claim 15, wherein the metallization structures comprise metallization structures created using a wafer-level process (WLP).

18. The coupled inductor of claim 17, wherein the metallization structures comprise at least one redistribution layer (RDL).

19. The coupled inductor of claim 14, wherein the insulating layer comprises a magnetic molding compound.

20. The coupled inductor of claim 14, wherein the coupled inductor is incorporated into an integrated voltage regulator circuit.

21. The coupled inductor of claim 20, wherein the integrated voltage regulator circuit is incorporated into system-on-chip (SOC) device.

22. The coupled inductor of claim 21, wherein the SOC device is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

23. A method for fabricating a coupled inductor, the method comprising:
providing a substrate;
forming, on the substrate, a plurality of metallization structures, each metallization structure comprising a plurality of metal layers electrically connected in parallel with each other; and
connecting the plurality of metallization structures using wire bonds to create a pair of inductors, each inductor comprising an alternating series of metallization structures and wire bonds forming a spiral topology around a common central axis,
wherein the pair of inductors are interleaved with each other along the common central axis, such that at least some of the metallization structures of one of the pair of inductors are electrically coupled with at least some of the metallization structures of the other of the pair of inductors, and at least some of the wire bonds of one of the pair of inductors are electrically coupled with at least some of the wire bonds of the other of the pair of inductors.

24. The method of claim 23, wherein forming the plurality of metallization structures comprises forming the plurality of metal layers in a vertical stack, separated from each other by a respective insulating layer, and electrically connected to each other by one or more vias through the respective insulating layer.

25. The method of claim 23, wherein forming the plurality of metallization structures comprises forming the plurality of metallization structures using a wafer-level process (WLP).

26. The method of claim 25, wherein forming the plurality of metallization structures comprises forming at least one redistribution layer (RDL).

27. The method of claim 23, further comprising encasing the wire bonds within an insulating material.

28. The method of claim 27, wherein encasing the wire bonds within an insulating material comprise encasing the wire bonds within a magnetic molding compound.

29. A method for fabricating a coupled inductor, the method comprising:
providing a substrate;
forming, on the substrate, a plurality of first-level metallization structures, each first-level metallization structure comprising a plurality of metal layers electrically connected in parallel with each other;
forming an insulating layer above the plurality of first-level metallization structures;
forming a plurality of vias that are electrically coupled to the plurality of first-level metallization structures through the insulating layer; and
forming, on the insulating layer, a plurality of second-level metallization structures to create a pair of inductors, each inductor comprising an alternating series of first-level metallization structures and second-level metallization structures separated by the insulating layer and electrically connected to each other by the vias through the insulating layer, and forming a spiral topology around a common central axis,
wherein the pair of inductors are interleaved with each other along the common central axis such that at least some of the first-level metallization structures of one of the pair of inductors are electrically coupled with at least some of the first-level metallization structures of the other of the pair of inductors, and at least some of the second-level metallization structures of one of the pair of inductors are electrically coupled with at least some of the second-level metallization structures of the other of the pair of inductors.

30. The method of claim 29, wherein forming the insulating layer comprises forming a magnetic mold compound layer.
